(19) United States
(12) Patent Application Publication
(10) Pub. No.: US 2026/0082862 A1
(43) Pub. Date: Mar. 19, 2026

(54) CHIP AND TRANSFER SUBSTRATE BASED ON LOW-MODULUS SUPRAMOLECULAR COATING MATERIAL AND TRANSFER METHOD

(71) Applicant: BEIJING UNIVERSITY OF CHEMICAL TECHNOLOGY, Beijing (CN)

(72) Inventors: Feng SHI, Beijing (CN); Mengjiao CHENG, Beijing (CN); Guiqiang ZHU, Beijing (CN)

(21) Appl. No.: 19/396,759

(22) Filed: Nov. 21, 2025

Related U.S. Application Data
(63) Continuation of application No. PCT/CN2024/095023, filed on May 23, 2024.

(30) Foreign Application Priority Data
May 25, 2023 (CN) 202310605235.2

(51) Int. Cl. H01L 21/683; H01L 23/29; H10H 29/03

(52) U.S. Cl. CPC H10P 72/7402; H10H 29/03; H10W 74/47; H10P 72/7412; H10P 72/7432; H10P 72/744

(57) ABSTRACT

A chip based on a low-modulus supramolecular coating material includes a chip body and a low-modulus supramolecular coating provided on one side of the chip away from a growth substrate, wherein the chip body is of a cylindrical or columnar structure, the low-modulus supramolecular coating is completely or partially coated on a surface of the chip, and an area of the low-modulus supramolecular coating is less than or equal to an area of the chip body. The transfer substrate includes a substrate and a low-modulus supramolecular coating, wherein the low-modulus supramolecular coating is patterned and modified on a surface of the substrate to form a plurality of transfer sites, and a position and a size of each transfer site correspond to distribution and sizes of the transferred chips. The present application addresses problems such as complicated structures, relatively low transfer efficiency, poor precision and vulnerability of the transferred chips.

### CROSS-REFERENCE TO RELATED APPLICATION

This application is a Continuation of International Application Number PCT/CN2024/095023 filed May 23, 2024, which claims priority to Chinese Patent Application No. 202310605235.2, filed on May 25, 2023, entitled “Chip and Transfer Substrate Based on Low-Modulus Supramolecular Coating Material and Transfer Method”, filed with the China National Intellectual Property Administration (CNIPA), the entire contents of which are incorporated herein by reference.

### TECHNICAL FIELD

The present application relates to the technical field of semiconductors, and more particularly relates to a chip and a transfer substrate based on a low-modulus supramolecular coating material and a transfer method.

### BACKGROUND ART

Pick & Place technology is a technique which utilizes a transfer substrate to transfer a large number of microelectronic components from a growth substrate to a driving substrate, so as to assemble an orderly integrated array in a two-dimensional or three-dimensional space. Due to high compatibility with existing technologies, high transfer efficiency and broad applicability to diverse materials, this technique is often used in the integration and preparation of various electronic devices, such as micro-LED displays, flexible solar cells, thin film transistors, flexible capacitors, sensor arrays, and flexible electrodes. These functional systems and devices require increasingly diversified materials and have increasingly complicated structures, and accordingly higher requirements are placed on the transfer technology.

When mass transfer of chips is achieved by Pick & Place technology, there are the following defects.
1) Modulating the adhesion between the transfer substrate and the components presents a significant challenge in Pick & Place technology. In the Pick & Place technology, a strong adhesive force between the transfer substrate and the chips is required when the chips are picked up from a growth wafer. During the release of components onto the receiving substrate, weak adhesion between the transfer substrate and the chips is required. Therefore, the key to successful transfer is to manipulate and adjust an interfacial adhesive force of the transfer substrate/chips. In the existing technologies, there are two primary strategies for adjusting the interfacial adhesive force of the transfer substrate/chips: first, the surface of the transfer substrate is modified; and second, the structure of the transfer substrate is designed. The surface modification is generally performed by adding a stimulus-responsive adhesive tape on the transfer substrate. Upon application of an appropriate external stimulus, dynamic regulation of the adhesion force is achieved, thereby completing the transfer process. However, this approach has limitations: on the one hand, it is difficult to avoid residues of the adhesive tape on the chips, which is extremely likely to affect the performance of the chips; and on the other hand, it is difficult to reuse the adhesive tape, which increases costs. The structure design is to design a special structure inside the transfer substrate to endow a transfer head with deformability, magnetic control capability, electrostatic control capability, and so on. During the transfer process, the adhesion between the chip and the transfer head is regulated by adjusting external conditions. For this strategy, the transfer substrate is complicated in structure and difficult to prepare, and meanwhile each transfer head is also caused to be larger, which limits the capability of transferring small-sized or high-density chips.
2) During the pick-up process, the transfer substrate must apply additional pressure to the chip, which can easily lead to chip damage. In the pick-up process, in order to bring the chips into close contact with the transfer substrate to achieve strong adhesion between the two, it is often necessary to apply pressure to the chips through the transfer substrate. However, most of the chips are made of brittle materials and have poor toughness, and this pressure application process may cause damage or fracture of the chips, thereby affecting the transfer yield. Meanwhile, the applied additional pressure may also cause lateral displacement of the chips, thereby reducing the transfer precision.

In view of this, when mass transfer of the chips is achieved by utilizing existing Pick & Place technology, there are problems such as complicated structures of the transfer substrate, low transfer efficiency, poor precision and vulnerability of the transferred chips. There is an urgent need for those skilled in the art to provide a novel strategy to solve the above problems.

### SUMMARY OF THE INVENTION

### Objective of the Present Application

For this reason, the present application provides a chip and a transfer substrate based on a low-modulus supramolecular coating material and a transfer method, so as to solve the problems in the existing Pick & Place technology.

### Solutions

In order to achieve the above object, the present application provides the following technical solutions:
the present application provides a chip based on a low-modulus supramolecular coating material.

The chip comprises a chip body and a low-modulus supramolecular coating which disposed on one side of the chip away from a growth substrate, wherein the chip body is of a cylindrical or columnar structure, the low-modulus supramolecular coating is completely or partially coated on a surface of the chip, and an area of the low-modulus supramolecular coating is less than or equal to an area of the chip body.

In some embodiments, the chip is composed of single or composite materials selected from metal, gallium nitride, and silicon dioxide.

In some embodiments, the transfer substrate includes a substrate and a low-modulus supramolecular coating, wherein the low-modulus supramolecular coating is patterned and modified on a surface of the substrate to form a plurality of transfer sites, and a position and a size of each transfer site correspond to distribution and sizes of the transferred chips.

In some embodiments, the substrate is composed of a metal, plastic or silicon dioxide material.

In some embodiments, the substrate is capable of receiving a specific stimulus consisting of ultraviolet light, infrared light, heat or visible light.

In some embodiments, the low-modulus supramolecular coating exhibits a modulus of 10 MPa or below, which contains supramolecular functional groups. The preparation method is that a synthesis can be performed through a one-step method by directly adding supramolecular functional groups in a polymerization process of the low-modulus supramolecular coating, or a synthesis can be performed through a two-step method by firstly modifying the low-modulus coating and then introducing the supramolecular functional groups through surface modification.

The present application further provides a chip Pick & Place technology, including steps of:
In the pick-up process, bringing the low-modulus coating on the transfer substrate surface containing supramolecular functional group A into contact with the low-modulus coating on the chip surface containing supramolecular functional group a. The supramolecular interaction occurs between the two to generate an acting force; lifting up the transfer substrate, separating the chips from the growth substrate, and successfully picking up the chips.

During the place process, moving the transfer substrate/chips above the driving substrate, applying a specific stimulus, weakening a supramolecular acting force between the supramolecular functional groups A and the supramolecular functional groups a, an interface of the transfer substrate/chips being in a weak adhesive state, and successfully releasing the chips.

In some embodiments, an external stimulus is applied to the entire transfer substrate or some positions of the transfer substrate to release all or some of the chips.

In some embodiments, the supramolecular functional groups include any one of:
specific hybridization of two complementary DNA chains, reversible covalent bonds represented by a disulfide bond, specific biological recognition represented by biotin-avidin, host-guest interaction represented by cyclodextrin and azobenzene, electrostatic interaction between positive charges and negative charges, click chemical reaction represented by azide and alkyne groups, photochemical reaction represented by coumarin dimerization, coordination bond and hydrogen bond interaction between ligands and receptors, or charge transfer interaction.

### Beneficial Effects

In one or more specific embodiments, the chip and the transfer substrate based on the low-modulus supramolecular coating material and the transfer method provided in the present application have at least the following technical effects.
1. The solution provided by the present application leverages the reversibility of supramolecular assembly to achieve dynamic regulation of the adhesion force between the transfer substrate and the chip during the Pick & Place process. Compared with a traditional Pick & Place technology, this transfer substrate is simple in structure and does not need a complicated structure; and compared with other surface modification strategies, this transfer substrate has an adhesive force which can be changed by 30-fold or higher and can be recycled, thereby effectively improving the transfer efficiency and reducing the use costs.
2. The solutions provided in the present application can provide effective protection for the chips. In a pick-up process, due to the presence of the low-modulus supramolecular coating, the transfer substrate can generate a sufficient bonding force with the chips without applying additional pressure to achieve the pick-up process; at the same time the low-modulus supramolecular coatings on the surfaces of the chips serve as an elastic material, which can effectively dissipate external impact energy and protect the chips. The combination of the two can effectively protect the chips in a transfer process, so as to prevent the fracture of the chips in the transfer process.
3. The solutions provided in the present application can effectively improve the transfer precision. The pick-up process can be achieved without applying additional pressure or long-time contact to the chips in the pick-up process, which may effectively prevent the lateral offset of the chips caused by the application of the additional pressure and improve the transfer precision.

In summary, the present application effectively addresses the limitations of existing Pick & Place technologies, such as complicated structures of the transfer substrate and other equipment(s), relatively low transfer efficiency, poor precision and vulnerability of the transferred chips.

### BRIEF DESCRIPTION OF THE DRAWINGS

In order to more clearly explain the technical solutions in the embodiments of the present application or in the prior art, a brief introduction will be made to the accompanying drawings, which are required to be used in the description of the embodiments or the prior art. It is apparent that the drawings in the following description are only exemplary, and for those ordinarily skilled in the art that other implementation drawings may also be derived from the provided drawings without involving any inventive effort.

The structures, proportions, sizes, and the like depicted in this specification are only used to complement the contents disclosed in the specification for the understanding and reading of those skilled in the art, are not intended to set the limiting conditions for the implementation of the present application, and therefore do not have any substantive technical significance. Any modification of the structure, change of the proportional relationship or adjustment of the size should still fall within the scope which can be covered by the technical contents disclosed in the present application without affecting the efficacy that the present application can produce and the object that the present application can achieve.

FIG. 1 is a schematic structural diagram I of micro-LED chips on a growth wafer;

FIG. 2 is a schematic structural diagram of a transfer substrate a;

FIGS. 3A and 3B is a schematic diagram showing a process of picking up the micro-LED chips by the transfer substrate a, wherein FIG. 3A is a schematic diagram showing alignment of the transfer substrate a and the micro-LED chips, and FIG. 3B is a schematic diagram showing the pick-up of the micro-LED chips;

FIGS. 4A and 4B is a schematic diagram showing a process of releasing the micro-LED chips by the transfer substrate a, wherein FIG. 4A is a schematic diagram showing alignment of the micro-LED chips and an assembly substrate, and FIG. 4B is a schematic diagram showing the releasing of the micro-LED chips;

FIG. 5 is a schematic structural diagram II of micro-LED chips on a growth wafer;

FIG. 6 is a schematic structural diagram of a transfer substrate b;

FIGS. 7A and 7B is a schematic diagram showing a process of picking up the micro-LED chips by the transfer substrate b, wherein FIG. 7A is a schematic diagram showing alignment of the transfer substrate b and the micro-LED chips, and FIG. 7B is a schematic diagram showing the pick-up of the micro-LED chips; and

FIGS. 8A and 8B is a schematic diagram showing a process of releasing the micro-LED chips by the transfer substrate b, wherein FIG. 8A is a schematic diagram showing alignment of the micro-LED chips and an assembly substrate, and FIG. 8B is a schematic diagram showing the placement of the micro-LED chips.

### DESCRIPTION OF REFERENCE NUMERALS

1-growth wafer, 2-micro-LED chip, 3-low-modulus supramolecular coating A;
4-substrate a, 5-low-modulus supramolecular coating a, 6-transfer substrate a;
7-low-modulus supramolecular coating B, 8-substrate b, 9-low-modulus supramolecular coating b,
10-transfer substrate b; and 11-receiving substrate.

### DETAILED DESCRIPTION OF THE INVENTION

The embodiments of the present application will be illustrated below with specific examples, and other advantages and effects of the present application may be readily understood by those skilled in the art from the contents disclosed in this specification. It is apparent that the described examples are some but not all of the examples of the present application. All other examples obtained by those ordinarily skilled in the art based on the examples in the present application without making any inventive effort fall within the scope of protection of the present application.

In a specific embodiment, the present application provides a chip based on a low-modulus supramolecular coating material, consisting of a chip body and a low-modulus supramolecular coating, which disposed on one side of the chip away from a growth substrate, wherein the chip body is of a columnar structure such as a prism-like structure. The low-modulus supramolecular coating is completely or partially coated on a surface of the chip, and an area of the low-modulus supramolecular coating is less than or equal to an area of the chip. The chip composed of single or composite materials such as metal, gallium nitride, and silicon dioxide.

For use in conjunction with the above chip, the present application further provides a transfer substrate based on a low-modulus supramolecular coating material, consisting of two parts, namely, a substrate and a low-modulus supramolecular coating, wherein the low-modulus supramolecular coating is patterned and modified on a surface of the substrate to form a plurality of transfer sites, and a position and a size of each transfer site correspond to distribution and sizes of the transferred chips; and wherein the substrate can be made of a hard material such as a metal, plastic and silicon dioxide, or a soft material such as polydimethylsiloxane, and the substrate can receive a specific stimulus such as ultraviolet light, infrared light, heat and visible light.

In the chip and transfer substrate based on the low-modulus supramolecular coating material described above. The low-modulus supramolecular coating exhibits a modulus of 10 MPa or below, which contains supramolecular functional groups A. The preparation method is that a synthesis can be performed through a one-step method by directly adding the supramolecular functional groups in a polymerization process of the low-modulus supramolecular coating; and a synthesis can also be performed through a two-step method by firstly modifying the low-modulus coating and then introducing the supramolecular functional groups through surface modification.

The present application further provides a chip Pick & Place technology, being implemented based on transferring a corresponding chip by the transfer substrate as described above, and including the steps of:

In the pick-up process, bringing the low-modulus coating on the transfer substrate surface containing supramolecular functional group A into contact with the low-modulus coating on the chip surface containing supramolecular functional group a. The supramolecular interaction occurs between the two to generate an acting force; lifting up the transfer substrate, separating the chips from the growth substrate, and successfully picking up the chips.

During the place process, moving the transfer substrate/chips above the driving substrate, applying a specific stimulus, weakening a supramolecular acting force between the supramolecular functional groups A and the supramolecular functional groups a, an interface of the transfer substrate/chips being in a weak adhesive state, and successfully releasing the chips.

Specifically, an external stimulus can be applied to the entire transfer substrate to achieve a large-scale efficient transfer process, and can also be applied to some positions of the transfer substrate to achieve a transfer process of some chips.

The above supramolecular functional groups include all combinations of chemical functional groups which can interact in a short time, for example: specific hybridization of two complementary DNA chains, reversible covalent bonds represented by a disulfide bond, specific biological recognition represented by biotin-avidin, host-guest interaction represented by cyclodextrin and azobenzene, electrostatic interaction between positive charges and negative charges, click chemical reaction represented by azide and alkyne groups, photochemical reaction represented by coumarin dimerization, coordination bond and hydrogen bond interaction between ligands and receptors, charge transfer interaction, and the like.

In order to facilitate understanding, several examples are set forth below to provide a brief description of the implementation processes of the solutions provided in the present application.

### Example 1

Step 1, micro-LED chips 2 were prepared on a growth wafer 1, and low-modulus supramolecular coatings A 3 were prepared on surfaces of the prepared micro-LED chips 2. As shown in FIG. 1, the surfaces of the chips containing azobenzene supramolecular functional group A were modified with the low-modulus supramolecular coatings A 3 The low-modulus supramolecular coatings A 3 can be composed of single or composite materials selected from materials such as hydrogel, layer-by-layer assembled multilayer film, and polymer brush, and the low-modulus supramolecular coatings A 3 can be modified by various methods such as digital photolithography, layer-by-layer assembly technology, surface hydrogel coating modification, and surface polymerization.

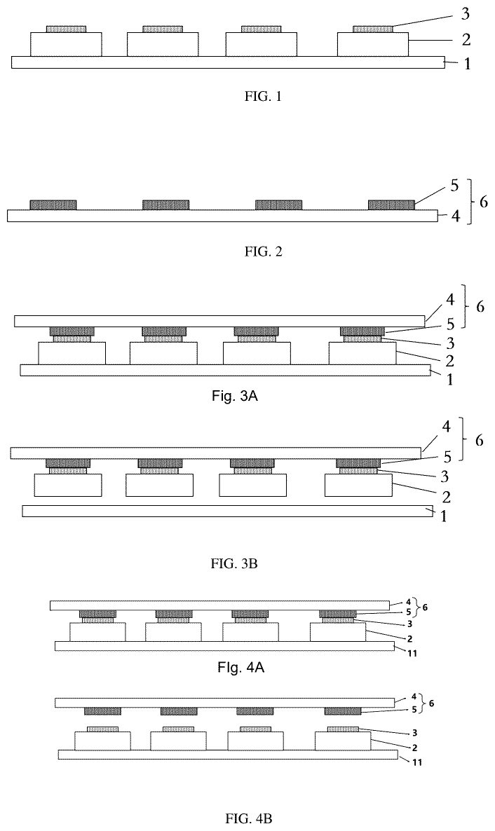

Step 2, a surface of the substrate a 4 was modified with patterned low-modulus supramolecular coatings a 5 to constitute a transfer substrate a 6. As shown in FIG. 2, the transfer substrate a 6 consisted of two parts, namely, the substrate a 4 and the low-modulus supramolecular coatings a 5. According to an array of micro-LED chips 2 to be transferred, the patterned low-modulus supramolecular coatings a 5 was modified on the substrate a 4 to form a plurality of transfer sites, and positions and sizes of the transfer sites corresponded to positions and sizes of the micro-LED chips 2 on the growth wafer 1. Supramolecular functional groups a was cyclodextrin. The low-modulus supramolecular coatings can be composed of single or composite materials selected from materials such as hydrogel, layer-by-layer assembled multilayer film, and polymer brush; and the low-modulus supramolecular coatings can be modified by various methods such as digital photolithography, layer-by-layer assembly technology, surface hydrogel coating modification, and surface polymerization. The transfer substrate a 6 as a whole was of a light-transmitting structure to facilitate the application of an ultraviolet light stimulus.

Step 3, a pick-up process of the micro-LED chips 2 was provided. The transfer substrate a 6 approached the array of the micro-LED chips 2 to be transferred, to bring the low-modulus supramolecular coatings A 3 into contact with the low-modulus supramolecular coatings a 5. Additional pressure was not required to be applied herein, and the transfer substrate a 6 can generate a sufficient adhesive force with the micro-LED chips 2 based on supramolecular interaction between them, so that the micro-LED chips 2 were separated from the growth wafer 1 and the micro-LED chips 2 were picked up. FIGS. 3A and 3B is a schematic diagram showing a process of picking up the micro-LED chips 2 by the transfer substrate a 6; wherein FIG. 3A is a schematic diagram showing alignment of the transfer substrate a 6 and the micro-LED chips 2, and FIG. 3B is a schematic diagram showing the pick-up of the micro-LED chips 2.

Step 4, a placing process of the micro-LED chips 2 was provided. The transfer substrate a 6 carried the micro-LED chips 2 onto a receiving substrate 11, so as to achieve the alignment of the micro-LED chips 2 and assembly positions on the receiving substrate 11, and ultraviolet light irradiation adjusted the intensity of supramolecular interaction between the micro-LED chips 2 and the transfer substrate a6, so that the adhesion force was weakened, thereby achieving the separation of them and releasing the micro-LED chips 2 onto the receiving substrate 11. The supramolecular interaction between the micro-LED chips 2 and the transfer substrate a6 had good reversibility, so that the substance and the chips can be repeatedly adhesive and dissociated under specific conditions, so as to achieve controllable adhesive and separation of the micro-LED chips 2 and the transfer substrate a 6, and complete multiple picking and placing operations. Therefore, the transfer substrate a 6 can be recycled. If it was necessary to transfer all the micro-LED chips 2 at one time, full-area ultraviolet light irradiation can be applied to the transfer substrate a 6; and if it was necessary to transfer a designated micro-LED chip 2, ultraviolet light can be selectively applied by utilizing a mask to irradiate a designated area in this step.

FIGS. 4A and 4B is a schematic diagram showing a process of releasing the micro-LED chips 2 by the transfer substrate a 6; wherein FIG. 4A is a schematic diagram showing alignment of the array of the micro-LED chips 2 and the receiving substrate 11, and FIG. 4B is a schematic diagram showing the releasing of the micro-LED chips 2.

Step 5, aftertreatment was performed on an assembled body of the micro-LED chips 2 and the receiving substrate 11 to complete subsequent processes, such as circuit welding and packaging.

### Example 2

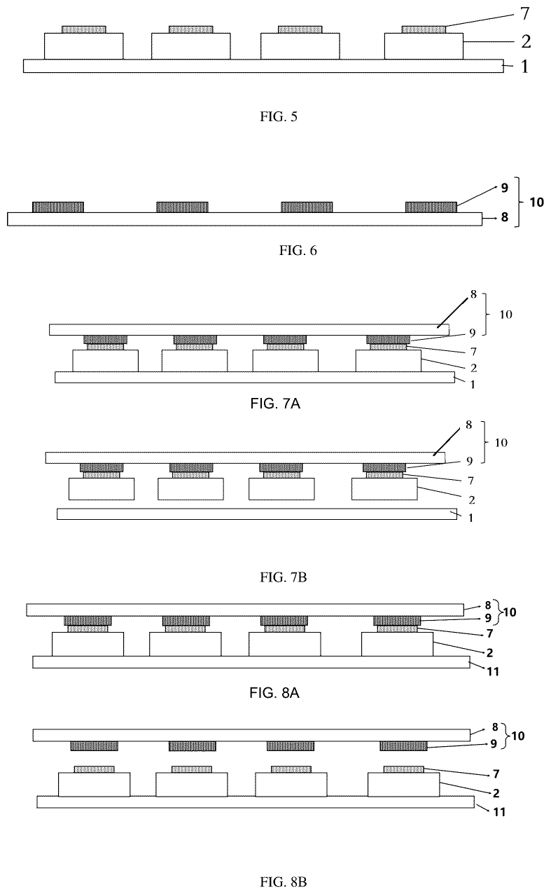

Step 1, low-modulus supramolecular coatings B 7 were modified into the micro-LED chips 2 which orderly arranged on a growth wafer 1, and a structure was as shown in FIG. 5. Supramolecular functional groups B were guest molecules, namely, benzylic molecules. The low-modulus supramolecular coatings were composed of single or composite materials selected from hydrogel, layer-by-layer assembled multilayer film, and polymer brush. The low-modulus supramolecular coatings can be modified by various methods such as digital photolithography, layer-by-layer assembly technology, surface hydrogel coating modification, and surface polymerization.

Step 2, a surface of a substrate b 8 was modified with patterned low-modulus supramolecular coatings b 9 to constitute a transfer substrate b 10. As shown in FIG. 6, the transfer substrate b 10 consisted of two parts, namely, the substrate b 8 and the low-modulus supramolecular coatings b 9. According to an array of micro-LED chips 2 to be transferred, the patterned low-modulus supramolecular coatings b 9 were modified on the substrate b 8 to form a plurality of transfer sites. Positions and sizes of the transfer sites corresponded to positions and sizes of the micro-LED chips 2 on the growth wafer 1. A supramolecular functional group b was a host molecule (cyclodextrin). The coatings can be composed of single or composite materials selected from materials such as hydrogel, layer-by-layer assembled multilayer film, and polymer molecular brush; and the coatings can be modified by various methods such as digital photolithography, layer-by-layer assembly technology, surface hydrogel coating modification, and surface polymerization. The substrate b 8 contained a photothermal conversion material, and can be heated locally or globally under the irradiation of external infrared light.

Step 3, a pick-up process of the micro-LED chips 2 was provided. The transfer substrate b 10 approached the array of the micro-LED chips 2 to be transferred, so as to bring the low-modulus supramolecular coatings B 7 and the low-modulus supramolecular coatings b 9 into contact. Additional pressure was not required to be applied, and the transfer substrate b 10 can generate a sufficient adhesive force with the micro-LED chips 2 based on host-guest interaction between the two, so that the micro-LED chips 2 were separated from the growth wafer 1 and the micro-LED chips 2 were picked up. FIGS. 7A and 7B is a schematic diagram showing a process of picking up the micro-LED chips 2 by the transfer substrate b; wherein FIG. 7A is a schematic diagram showing alignment of the transfer substrate b and the micro-LED chips 2, and FIG. 7B is a schematic diagram showing the pick-up of the micro-LED chips 2.

Step 4, a placing process of the micro-LED chips 2 was provided. The transfer substrate b 10 carrying the micro-LED chips 2 was transferred onto a receiving substrate 11, so as to achieve the alignment of the micro-LED chips 2 and assembly positions on the receiving substrate 11. Infrared light irradiated the substrate b 8, and the substrate b 8 was heated due to the photothermal conversion material contained therein, so that the intensity of supramolecular interaction between the micro-LED chips 2 and the transfer substrate b 8 was adjusted, and an adhesive force thereof was weakened, thereby achieving the separation of the two and placing the micro-LED chips 2 onto an assembly substrate. The supramolecular interaction between the micro-LED chips 2 and the transfer substrate b 10 had good reversibility, so that the two can be repeatedly adhesive and dissociated under specific conditions, so as to achieve controllable adhesive and separation of the micro-LED chips 2 and the transfer substrate b 10, and complete multiple picking and placing operations. Therefore, the transfer substrate b 10 can be recycled. If it was necessary to transfer all the micro-LED chips 2 at one time, full-area infrared light irradiation can be applied to the transfer substrate b 10 to achieve global heating for the transfer substrate b 10 in this step; and if it was necessary to transfer a designated micro-LED chip 2, infrared light can be selectively applied by utilizing a mask to irradiate a designated area to achieve local heating for the transfer substrate b 10 in this step. FIGS. 8A and 8B is a schematic diagram showing a process of releasing the micro-LED chips 2 by the transfer substrate b; wherein FIG. 8A is a schematic diagram showing alignment of the array of the micro-LED chips 2 and the assembly substrate, and FIG. 8B is a schematic diagram showing the placement of the micro-LED chips 2.

Step 5, welding and packaging processes were identical to the processes in Example 1.

In one or more specific embodiments, the chip and the transfer substrate based on the low-modulus supramolecular coating material and the transfer method provided in the present application have at least the following technical effects.
1. The solution provided by the present application leverages the reversibility of supramolecular assembly to achieve dynamic regulation of the adhesion force between the transfer substrate and the chip during the Pick & Place process. Compared with a traditional Pick & Place technology substrate with a special structure, this transfer substrate is simple in structure and does not need a complicated structure; and compared with other surface modification strategies, this transfer substrate has an adhesive force which can be changed by 30-fold or higher and can be recycled, thereby effectively improving the transfer efficiency and reducing the use costs.
2. The solutions provided in the present application can provide effective protection for the chips. In a pick-up process, due to the presence of the low-modulus supramolecular coating, the transfer substrate can generate a sufficient bonding force with the chips without applying additional pressure to achieve the pick-up process; at the same time, the low-modulus supramolecular coatings on the surfaces of the chips serve as an elastic material, which can effectively dissipate external impact energy and protect the chips. The combination of the two can effectively protect the chips in a transfer process, so as to prevent the fracture of the chips in the transfer process.
3. The solutions provided in the present application can effectively improve the transfer precision. The pick-up process can be achieved without applying additional pressure or long-time contact to the chips in the pick-up process, which may effectively prevent the lateral offset of the chips caused by the application of the additional pressure and improve the transfer precision.

In summary, the present application effectively addresses the limitations of existing Pick & Place technologies, such as complicated structures of the transfer substrate and other equipment(s), relatively low transfer efficiency, poor precision and vulnerability of the transferred chips.

The objects, technical solutions and beneficial effects of the present application have been described in further detail in the above specific embodiments. It should be understood that the foregoing is merely the specific embodiments of the present application and is not intended to limit the scope of protection of the present application. Any modification, equivalent replacement, improvement, and the like made on the basis of the technical solutions of the present application should be included within the scope of protection of the present application.

1. A chip based on a low-modulus supramolecular coating material, comprising a chip body and a low-modulus supramolecular coating which disposed on one side of the chip away from a growth substrate, wherein the chip body is of a columnar structure, the low-modulus supramolecular coating is completely or partially coated on a surface of the chip, and an area of the low-modulus supramolecular coating is less than or equal to an area of the chip body.

2. The chip based on a low-modulus supramolecular coating material according to claim 1, wherein the chip is composed of single or composite materials selected from the group consisting of metal, gallium nitride, and silicon dioxide.

3. The chip based on a low-modulus supramolecular coating material according to claim 1, wherein the low-modulus supramolecular coating has a modulus of 10 MPa or below and contains supramolecular functional groups therein, and a preparation method is that a synthesis is performed through a one-step method by directly adding supramolecular functional groups in a polymerization process of the low-modulus supramolecular coating, or a synthesis is performed through a two-step method by firstly modifying the low-modulus coating and then introducing the supramolecular functional groups through surface modification.

4. The chip based on a low-modulus supramolecular coating material according to claim 3, wherein the supramolecular functional groups comprise any one of: specific hybridization of two complementary DNA chains, reversible covalent bonds represented by a disulfide bond, specific biological recognition represented by biotin-avidin, host-guest interaction represented by cyclodextrin and azobenzene, electrostatic interaction between positive charges and negative charges, click chemical reaction represented by azide and alkyne groups, photochemical reaction represented by coumarin dimerization, coordination bond and hydrogen bond interaction between ligands and receptors, or charge transfer interaction.

5. A transfer substrate based on a low-modulus supramolecular coating material, for use in conjunction with the chip according to claim 1, wherein the transfer substrate comprises a substrate and a low-modulus supramolecular coating, the low-modulus supramolecular coating is patterned and modified on a surface of the substrate to form a plurality of transfer sites, and a position and a size of each transfer site correspond to distribution and sizes of the transferred chips.

6. The transfer substrate based on a low-modulus supramolecular coating material according to claim 5, wherein the base is composed of a metal, plastic or silicon dioxide material.

7. The transfer substrate based on a low-modulus supramolecular coating material according to claim 5, wherein the substrate is capable of receiving a specific stimulus consisting of ultraviolet light, infrared light, heat or visible light.

8. The transfer substrate according to claim 5, wherein the low-modulus supramolecular coating has a modulus of 10 MPa or less and contains supramolecular functional groups therein, and a preparation method is that a synthesis is performed through a one-step method by directly adding supramolecular functional groups in a polymerization process of the low-modulus supramolecular coating, or a synthesis is performed through a two-step method by firstly modifying the low-modulus coating and then introducing the supramolecular functional groups through surface modification.

9. The transfer substrate according to claim 8, wherein the supramolecular functional groups comprise any one of:
specific hybridization of two complementary DNA chains, reversible covalent bonds represented by a disulfide bond, specific biological recognition represented by biotin-avidin, host-guest interaction represented by cyclodextrin and azobenzene, electrostatic interaction between positive charges and negative charges, click chemical reaction represented by azide and alkyne groups, photochemical reaction represented by coumarin dimerization, coordination bond and hydrogen bond interaction between ligands and receptors, or charge transfer interaction.

10. A chip transfer method, being implemented based on the chip based on a low-modulus supramolecular coating material according to claim 1 and the transfer substrate and comprising steps of:
in the pick-up process, bringing the low-modulus coating on the transfer substrate surface containing supramolecular functional group A into contact with the low-modulus coating on the chip surface containing supramolecular functional group a; the supramolecular interaction occurring between the two to generate an acting force; lifting up the transfer substrate, separating the chips from the growth substrate, and successfully picking up the chips; and during the place process, moving the transfer substrate/chips above the driving substrate, applying a specific stimulus, weakening a supramolecular acting force between the supramolecular functional groups A and the supramolecular functional groups a, an interface of the transfer substrate/chips being in a weak adhesive state, and successfully releasing the chips.

11. The chip transfer method according to claim 10, wherein an external stimulus is applied to the entire transfer substrate or a specific position of the transfer substrate to achieve selective transfer of all or some of the chips.

12. The chip transfer method according to claim 10, wherein the supramolecular functional groups comprise any one of:
specific hybridization of two complementary DNA chains, reversible covalent bonds represented by a disulfide bond, specific biological recognition represented by biotin-avidin, host-guest interaction represented by cyclodextrin and azobenzene, electrostatic interaction between positive charges and negative charges, click chemical reaction represented by azide and alkyne groups, photochemical reaction represented by coumarin dimerization, coordination bond and hydrogen bond interaction between ligands and receptors, or charge transfer interaction.
